(19) United States
(12) Patent Application Publication
(10) Pub. No.: US 2025/0244397 A1
(43) Pub. Date: Jul. 31, 2025

(54) METHOD FOR ESTIMATING FULL CHARGE CAPACITY OF BATTERY

(71) Applicant: TOYOTA JIDOSHA KABUSHIKI KAISHA, Toyota-shi (JP)

(72) Inventor: Yoshimi HORIBE, Toyota-shi (JP)

(73) Assignee: TOYOTA JIDOSHA KABUSHIKI KAISHA, Toyota-shi (JP)

(21) Appl. No.: 18/926,605

(22) Filed: Oct. 25, 2024

(30) Foreign Application Priority Data
Jan. 31, 2024 (JP) 2024-013407

(51) Int. Cl. G01R 31/392; B60L 53/51; B60L 58/12; B60L 58/20; G01R 31/378; H02J 7/34; H02J 7/35

(52) U.S. Cl. CPC G01R 31/392; B60L 53/51; B60L 58/12; B60L 58/20; G01R 31/378; H02J 7/342; H02J 7/35

(57) ABSTRACT

A method of estimating a full charge capacity of a battery includes: a first step of charging the battery to a fully charged state; a second step of discharging the battery that is in the fully charged state with a first state of charge to a second state of charge; a third step of calculating a discharge capacity of the battery discharged during a discharge period from the first state of charge to the second state of charge; and a fourth step of estimating the full charge capacity of the battery based on the discharge capacity and a difference between the first state of charge and the second state of charge.

### CROSS-REFERENCE TO RELATED APPLICATION

This application claims priority to Japanese Patent Application No. 2024-013407 filed on Jan. 31, 2024, incorporated herein by reference in its entirety.

### BACKGROUND

### 1. Technical Field

The present disclosure relates to methods for estimating a full charge capacity of a battery mounted in a vehicle.

### 2. Description of Related Art

Japanese Unexamined Patent Application Publication No. 2008-261669 (JP 2008-261669 A) discloses a method that can accurately detect a full charge capacity of a battery without completely discharging or fully charging the battery. In the method described in JP 2008-261669 A, a full charge capacity of a battery is calculated based on a capacity change value and a rate of change in state of charge (remaining capacity) of the battery in a charging process from a lower limit of an open circuit voltage (no-load voltage) to an upper limit of the open circuit voltage.

### SUMMARY

JP 2008-261669 A is a technique of calculating a full charge capacity of a battery based on an open circuit voltage (OCV) that changes with a change in state of charge (SOC) of the battery. This technique is effective for ternary batteries etc. in which a change in open circuit voltage according to the state of charge of the battery can be easily seen. However, it is difficult to apply this technique to lithium iron phosphate batteries (LFP batteries) etc. whose SOC-OCV characteristic has a flat region, namely LFP batteries etc. in which a change in open circuit voltage according to the state of charge of the battery cannot be easily seen.

The present disclosure was made in view of the above issue, and an object of the present disclosure is to provide a full charge capacity estimation method that can suitably estimate even a full charge capacity of a battery whose SOC-OCV characteristic has a flat region.

In order to solve the above issue, an aspect of the technique of the present disclosure is
a method of estimating a full charge capacity of a battery. The method includes: charging the battery to a fully charged state;
discharging the battery that is in the fully charged state with a first state of charge to a second state of charge;
calculating a discharge capacity of the battery discharged during a discharge period from the first state of charge to the second state of charge; and
estimating the full charge capacity of the battery based on the discharge capacity and a difference between the first state of charge and the second state of charge.

With the method for estimating a full charge capacity of a battery according to the present disclosure, it is possible to suitably estimate even a full charge capacity of a battery whose SOC-OCV characteristic has a flat region.

### BRIEF DESCRIPTION OF THE DRAWINGS

Features, advantages, and technical and industrial significance of exemplary embodiments of the disclosure will be described below with reference to the accompanying drawings, in which like signs denote like elements, and wherein:

FIG. 1 is a schematic diagram of a functional block of a power supply system that implements a method for estimating a full charge capacity of a battery according to an embodiment of the present disclosure;

FIG. 2 is a flowchart of a process for estimating a full charge capacity of a battery according to an embodiment of the present disclosure; and

FIG. 3 shows an example of an SOC-OCV characteristic curve having a flat region.

### DETAILED DESCRIPTION OF EMBODIMENTS

In the method for estimating a full charge capacity of a battery according to the present disclosure, a battery discharge process is performed from a state of charge in a fully charged state to a predetermined low state of charge that is out of a flat region of an SOC-OCV characteristic, and the full charge capacity of the battery is estimated based on the discharge capacity and the amount of change (change range) in the state of charge during the discharge period.

Hereinafter, an embodiment of the present disclosure will be described in detail with reference to the drawings.

### EMBODIMENT

### Configuration

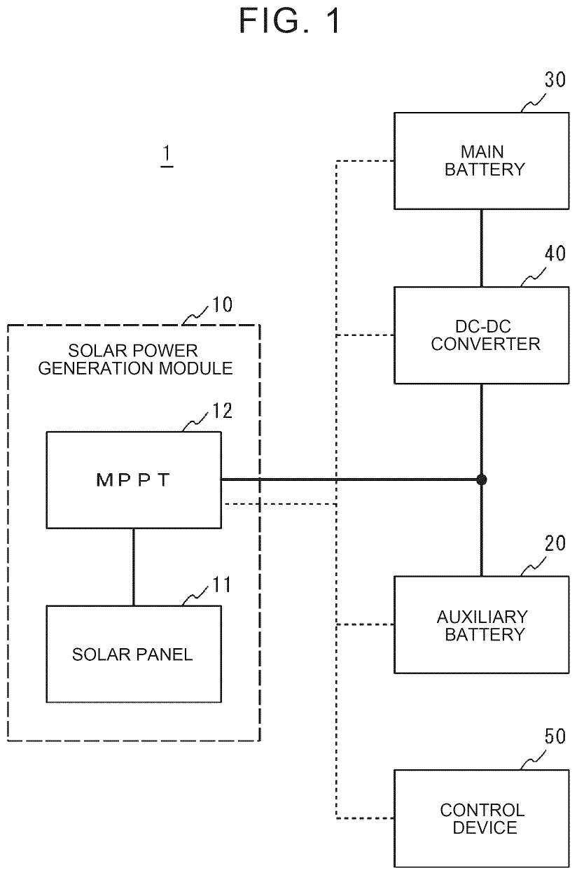

FIG. 1 is a schematic diagram illustrating an example of a functional block of a power supply system 1 that implements a method of estimating a full charge capacity of a battery according to an embodiment of the present disclosure. The power supply system 1 illustrated in FIG. 1 includes a solar power generation module 10, an auxiliary battery 20, a main battery 30, a DC-DC converter 40, and a control device 50. In FIG. 1, a connection line through which electric power flows is indicated by a solid line, and a connection line through which a detection signal, a control signal, or the like flows is indicated by a dotted line.

The power supply system 1 illustrated in FIG. 1 may be mounted on a vehicle using an electric motor as a power source. Such vehicles include hybrid electric vehicle (HEV), plug-in hybrid electric vehicle (PHEV), and battery electric vehicle (BEV).

The solar power generation module 10 is a power generation device that generates electric power by being irradiated with sunlight, and outputs the generated electric power to the auxiliary battery 20 and DC-DC converters 40 connected to the solar power generation module 10. The solar power generation module 10 includes a solar panel 11 and a MPPT12. The solar panel 11 is an assembly of solar cells. MPPT12 includes DC-DC converters for outputting power generated by the solar panel 11 at a predetermined voltage based on a maximum-power-point-following (MPPT) control.

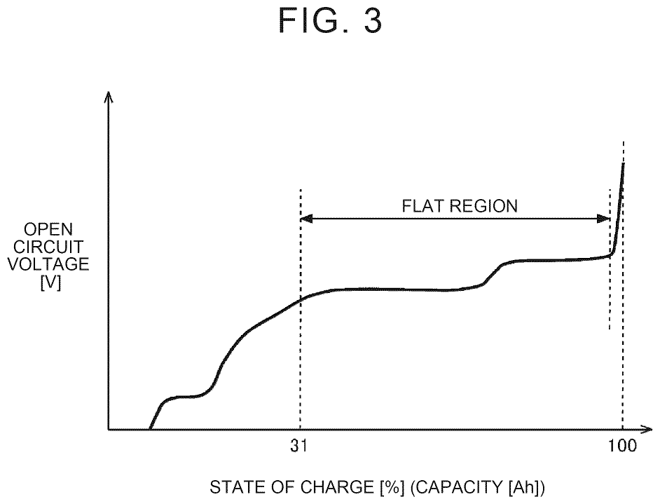

The auxiliary battery 20 is a secondary battery configured to be chargeable and dischargeable for supplying electric power to an auxiliary load (not shown) of the vehicle. Examples of the auxiliary battery 20 include a lithium-ion battery (for example, a LFP cell) whose SOC-OCV characteristic has a flat region in which an absolute value of a rate of change of an open circuit voltage (OCV) with respect to an electric state of charge (SOC) is equal to or less than a predetermined value. FIG. 3 shows an example of an SOC-OCV characteristic curve having a flat region. The auxiliary battery 20 is connected to the solar power generation module 10 so as to be able to be charged by electric power generated by the solar panel 11. The auxiliary battery 20 is connected to DC-DC converters 40 so that the main battery 30 can be charged by the electric power stored therein.

The main battery 30 is a secondary battery configured to be chargeable and dischargeable for supplying electric power to a main engine load (not shown) of the vehicle. As the main battery 30, a lithium ion battery can be exemplified. The main battery 30 is connected to the solar power generation module 10 and the auxiliary battery 20 via DC-DC converters 40 so as to be able to be charged by the electric power generated by the solar panel 11 and the electric power generated by the auxiliary battery 20. The main battery 30 is a battery (such as a driving battery) having a higher rated voltage than the auxiliary battery 20.

DC-DC converter 40 is a power converter capable of converting the inputted power into a predetermined-voltage power and outputting the converted power. DC-DC converters 40 have one end (primary side) connected to the solar power generation module 10 and the auxiliary battery 20, and the other end (secondary side) connected to the main battery 30. DC-DC converters 40 can supply (pump-charge) the electric power outputted from the solar power generation module 10 and the auxiliary battery 20 connected to the primary side to the main battery 30 connected to the secondary side. In addition, DC-DC converters 40 can supply (pump-out charge) the electric power of the main battery 30 connected to the secondary side to the auxiliary battery 20 connected to the primary side. The operation of DC-DC converters 40 is controlled by the control device 50.

The control device 50 is a configuration for controlling the power supply system 1. The control device 50 according to the present embodiment performs various processes and controls related to estimating the full charge capacity of the auxiliary battery 20. The control device 50 acquires information on the generated electric power from the solar power generation module 10, information on the physical quantity (voltage, current, state of charge, etc.) from the auxiliary battery 20, and information on the physical quantity (voltage, current, state of charge, etc.) from the main battery 30. A detection device such as a sensor is used to acquire the information. In addition, the control device 50 controls the operation of DC-DC converters 40 based on the acquired data and the like.

Some or all of the control device 50 may typically be configured as an electronic control unit (ECU: Electronic Control Unit) including a processor, memories, input/output interfaces, and the like. The electronic control unit realizes a predetermined function by the processor reading and executing a program stored in the memory.

### Control

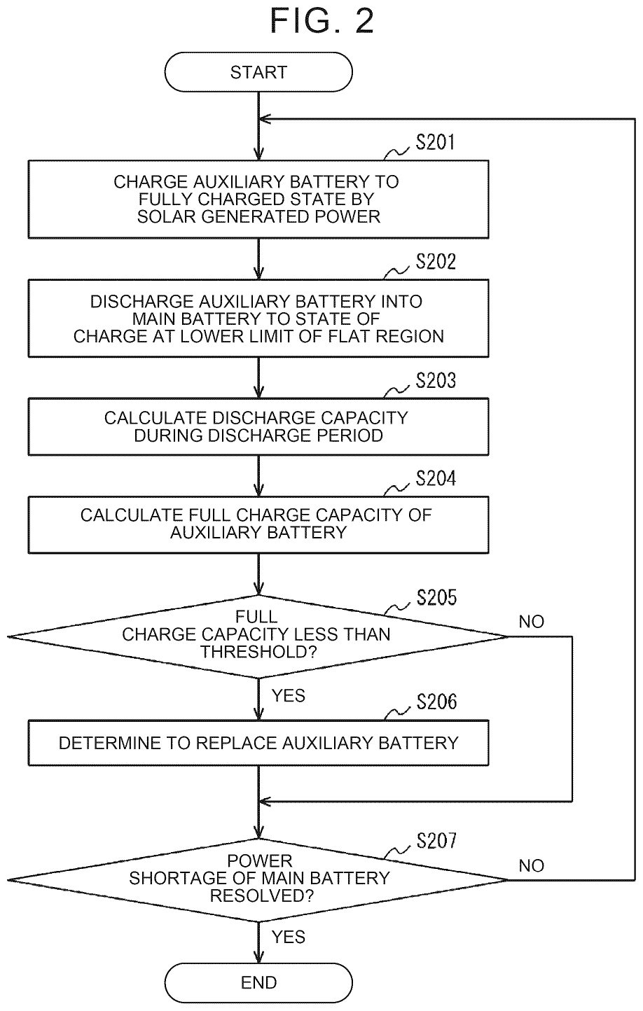

Next, with further reference to FIG. 2, a method for estimating a full charge capacity of a battery according to an embodiment of the present disclosure will be described. FIG. 2 is a flowchart illustrating a processing procedure of full charge capacity estimation control of the auxiliary battery 20 executed by the control device 50.

The full charge capacity estimation control of the auxiliary battery 20 illustrated in FIG. 2 is started when the electric power stored in the main battery 30 falls below a predetermined reference electric power (electric power is insufficient). This reference power is, for example, electric power that needs to be charged in order to suppress the battery from being dead, and is appropriately set based on power consumption of a main engine load using the main battery 30 as a power source, or the like.

### S201

The control device 50 charges the auxiliary battery 20 to a fully charged state with the generated electric power output from the solar power generation module 10. The fully charged state of the auxiliary battery 20 is typically a state in which the state of charge (or energy storage rate) of the auxiliary battery 20 becomes 100%. When the auxiliary battery 20 is fully charged, the process proceeds to S202.

### S202

After the auxiliary battery 20 is fully charged, the control device 50 discharges the electric power stored in the auxiliary battery 20 to the main battery 30 via DC-DC converters 40. That is, electric power is transferred from the auxiliary battery 20 to the main battery 30. This discharging is performed until the first state of charge (100%) of the auxiliary battery 20, which is in a fully charged state, is reduced to a predetermined second state of charge (31% in the embodiment of FIG. 3), which is at least the lower limit of the flat region in SOC-OCV characteristic. Note that the discharging may be performed continuously below the second state of charge. When the auxiliary battery 20 is discharged from the first state of charge to the second state of charge at the lower limit of the flat region, the process proceeds to S203.

### S203

The control device 50 calculates the discharge capacity [Ah (ampere-hour)] discharged from the auxiliary battery 20 to the main battery 30 during the discharge period from the first state of charge to the second state of charge by S202. The discharge capacity can be calculated based on a known current integration method or the like. In the embodiment of FIG. 3, the discharge period (hereinafter referred to as “section SOC”) from the first state of charge to the second state of charge is 69% (=100%−31%). When the discharge capacity in the section SOC is calculated, the process proceeds to S204.

### S204

The control device 50 calculates the full charge capacity of the auxiliary battery 20. The full charge capacity [Ah] can be calculated based on the section SOC [%] and the discharge capacity [Ah] in the section SOC according to Equation [1] below. When the full charge capacity of the auxiliary battery 20 is calculated, the process proceeds to S205.

Full charge capacity=discharge capacity of section SOC×(section SOC/100) [1]

### S205

The control device 50 determines whether or not the full charge capacity of the auxiliary battery 20 calculated by the above S204 is less than a predetermined threshold. This determination is made in order to check whether the auxiliary battery 20 is deteriorated. Therefore, the threshold is appropriately set based on the standard performance of the auxiliary battery 20, the frequency of use of the mounted vehicle, and the like. If the full charge capacity of the auxiliary battery 20 is less than the threshold (S205, Yes), the process proceeds to S206. On the other hand, when the full charge capacity of the auxiliary battery 20 is equal to or larger than the threshold (S205, No), the process proceeds to S207.

### S206

Since the auxiliary battery 20 is deteriorated, the control device 50 determines that the auxiliary battery 20 needs to be replaced. The determination result is preferably notified to a user of the vehicle, a server that centrally manages a plurality of vehicles, or the like. When it is determined that the auxiliary battery 20 needs to be replaced, the process proceeds to S207.

### S207

The control device 50 determines whether the power shortage of the main battery 30 has been eliminated (whether or not the stored power has become equal to or higher than a predetermined reference power). That is, the control device 50 determines whether the electric power of the main battery 30 has been sufficiently stored by the electric power transfer from the auxiliary battery 20 to the main battery 30 performed in the above S202. When the power shortage of the main battery 30 is resolved (S207, Yes), the full charge capacity estimation control of the auxiliary battery 20 ends. On the other hand, when the power shortage of the main battery 30 has not been solved yet (S207, No), S201 is returned and the full charge capacity estimation control of the auxiliary battery 20 is repeatedly performed.

### Operations and Effects

As described above, according to the method for estimating the full charge capacity of the battery according to the embodiment of the present disclosure, the auxiliary battery 20 is temporarily charged until the battery reaches the fully charged state (first state of charge). Further, the auxiliary battery 20 in the fully charged state is discharged from the open circuit voltage until the state of the low state of charge (second state of charge) in which the state of charge can be accurately estimated is reached. Then, the discharge capacity discharged from the auxiliary battery 20 during this discharge period is calculated, and the full charge capacity of the auxiliary battery 20 is estimated on the basis of the discharge capacity and the change in the state of charge due to the discharge.

In this way, even when the auxiliary battery 20 is an LFP cell etc. whose SOC-OCV characteristic has a flat region, the full charge capacity of the auxiliary battery 20 can be suitably estimated. As a method for bringing the auxiliary battery 20 into a fully charged state,

not only charging with the electric power generated by the solar power generation module 10 described above, but also charging with the regenerative electric power generated during traveling of the vehicle is exemplified. It is also possible to bring the auxiliary battery 20 into a fully charged state by charging from an external charger or the like connected when the vehicle is parked, or by pumping-up charging by electric power of the main battery 30.

Further, as a method for discharging the auxiliary battery 20 from the first state of charge to the second state of charge, in addition to transferring electric power from the auxiliary battery 20 to the main battery 30 described above, it is also possible to supply a dark current to the on-vehicle load during parking of the vehicle.

Although an embodiment of the present disclosure has been described above, the present disclosure can be regarded not only as the above-described method for estimating the full charge capacity of a battery, but also as a program of the method, a computer-readable non-transitory recording medium storing the program, or an apparatus for executing the full charge capacity estimation method.

The full charge capacity estimation method of the present disclosure can be used when it is desired to accurately estimate the full charge capacity of a battery.

What is claimed is:

1. A method of estimating a full charge capacity of a battery, the method comprising:
charging the battery to a fully charged state;
discharging the battery that is in the fully charged state with a first state of charge to a second state of charge;
calculating a discharge capacity of the battery discharged during a discharge period from the first state of charge to the second state of charge; and
estimating the full charge capacity of the battery based on the discharge capacity and a difference between the first state of charge and the second state of charge.

2. The method according to claim 1, wherein
the battery is a lithium-ion battery whose state of charge-open circuit voltage characteristic has a flat region, and a rate of change of an open circuit voltage with respect to a state of charge in the flat region is equal to or less than a predetermined value, and
in the discharging, the battery is discharged to the second state of charge, the second state of charge being a state of charge that is a lower limit of the flat region.

3. The method according to claim 1, wherein
the battery is an auxiliary battery mounted in a vehicle equipped with a solar power generation module, and
in the charging, the auxiliary battery is charged with electric power generated by the solar power generation module.

4. The method according to claim 3, wherein
a main battery is further mounted in the vehicle, and
in the discharging, the auxiliary battery is discharged into the main battery.

5. The method according to claim 1, further comprising determining that the battery needs to be replaced when the full charge capacity of the battery is less than a predetermined threshold.
